(19) United States
(12) Patent Application Publication
(10) Pub. No.: US 2017/0331475 A1
(43) Pub. Date: Nov. 16, 2017

(54) REFERENCE VOLTAGE BUFFER CIRCUIT

(71) Applicant: Realtek Semiconductor Corp., HsinChu (TW)

(72) Inventors: Yu-Chang Chen, New Taipei City (TW); Jie-Fan Lai, Taichung City (TW); Shih-Hsiung Huang, Miaoli County (TW)

(21) Appl. No.: 15/590,017

(22) Filed: May 9, 2017

(30) Foreign Application Priority Data
May 11, 2016 (TW) 105114511

(51) Int. Cl. H03K 19/00; G06G 7/186; G01R 31/317; G06F 1/10; H03K 17/296; H03K 5/13

(52) U.S. Cl. CPC H03K 19/00; H03K 17/296; H03K 5/13; G01R 31/31725; G06F 1/10; G06G 7/186

(57) ABSTRACT

A reference voltage buffer circuit includes an operational amplifier, a capacitor switching module, a first transistor and a second transistor. The operational amplifier includes two input terminals and an output terminal, where the two input terminals receive an input reference voltage and a feedback voltage, respectively. A gate electrode of the first transistor is coupled to the capacitor switching module, and a source electrode of the first transistor provides the feedback voltage. A gate electrode of the second transistor is coupled to the capacitor switching module, and a source electrode of the second transistor provides an output reference voltage. In addition, the operational amplifier generates a stable control voltage to the gate electrodes of the first transistor and the second transistors via the capacitor switching module while the output terminal of the operational amplifier is not directly connect to the gate electrodes of the first transistor and the second transistors.

### BACKGROUND OF THE INVENTION

### 1. Field of the Invention

The present invention relates to a reference voltage buffer circuit, and more particularly to a reference voltage buffer circuit applied to a low supply voltage system.

### 2. Description of the Prior Art

Please refer to FIG. 1, which is a diagram illustrating a reference voltage buffer circuit 100. As shown in FIG. 1, the reference voltage buffer circuit 100 comprises two operational amplifiers 110 and 120, four transistors M1-M4, and two resistors R1 and R2, and the reference voltage buffer circuit 100 is arranged to receive two input reference voltages Vinp and Vinn to generate two output reference voltages Vrefp and Vrefn, where the reference voltage buffer circuit 100 is supplied by a supply voltage VDD. Generally, a level of the output reference voltage Vrefp is equal to 0.75*VDD, and a level of the output reference voltage Vrefn is equal to 0.25*VDD. However, in the advanced semiconductor process, a supply voltage becomes lower, but a threshold voltage of transistors is not decreased with the supply voltage VDD, causing that gate voltages of the transistors M1 and M2 become too large and gate voltages of the transistors M3 and M4 become too low to function well.

For example, assuming that VDD=1V and the threshold voltages of the transistors M1-M4 are 0.4-0.5V, the gate voltages of the transistors M1 and M2 are required to be around 1.3V to make the circuits work stable. However, because the gate voltages of the transistors M1 and M2 are greater than the supply voltage VDD, in a conventional art the operational amplifier 110 needs to be supplied by another supply voltage greater than the supply voltage VDD, causing an increase of the design and manufacturing costs. In another conventional art, the transistors M1-M4 are implemented by low threshold voltage elements, however, the low threshold voltage elements may lower the speed of the transistors, and the system efficiency will be worsened.

### SUMMARY OF THE INVENTION

It is therefore an objective of the present invention to provide a reference voltage buffer circuit, which can generate a stable output reference voltage by using only one low supply voltage, and no low threshold voltage element is used in the reference voltage buffer circuit, to solve the above-mentioned problems.

In an embodiment of the present invention, a reference voltage buffer circuit comprises an operational amplifier, a capacitor switching module, a first transistor and a second transistor. The operational amplifier comprises two input terminals and an output terminal, where the two input terminals receive an input reference voltage and a feedback voltage, respectively. The capacitor switching module is coupled to the output terminal of the operational amplifier. A gate electrode of the first transistor is coupled to the capacitor switching module, and a source electrode of the first transistor is used to provide the feedback voltage. A gate electrode of the second transistor is coupled to the capacitor switching module, and a source electrode of the second transistor is used to provide an output reference voltage. In addition, the operational amplifier generates a stable control voltage to the gate electrodes of the first transistor and the second transistors via the capacitor switching module while the output terminal of the operational amplifier is not directly connect to the gate electrodes of the first transistor and the second transistors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a reference voltage buffer circuit.

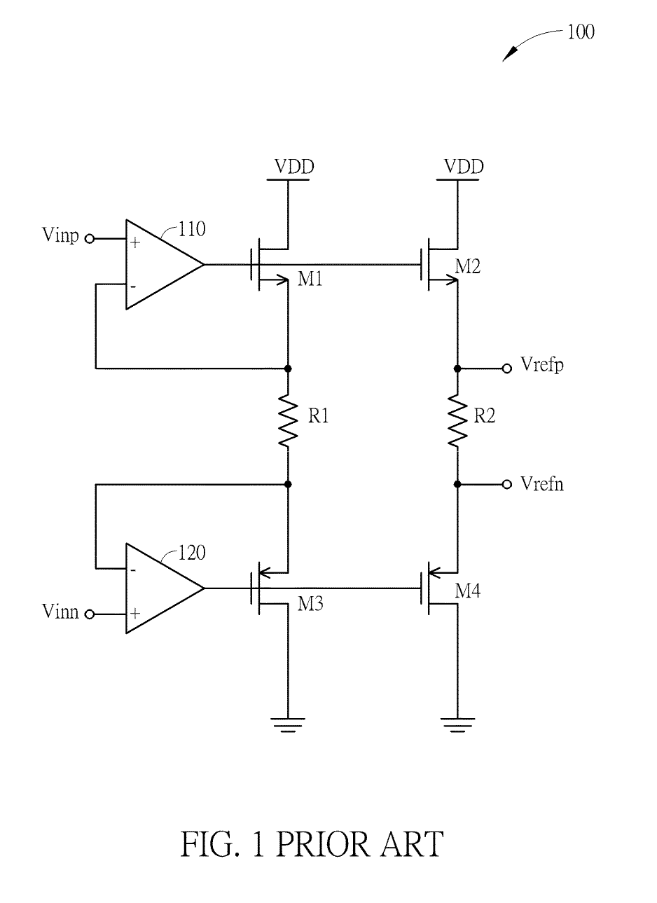

FIG. 2 is a diagram illustrating a reference voltage buffer circuit applied to an analog-to-digital converter according to one embodiment of the present invention.

FIG. 3 is a diagram showing a voltage divider.

FIG. 4 is a timing diagram of two clock signals.

FIG. 5 is a timing diagram of voltages of the terminals N1 and N2.

FIG. 6 is a diagram illustrating a reference voltage buffer circuit applied to an analog-to-digital converter according to another embodiment of the present invention.

FIG. 7 is a timing diagram of the control voltage and the output voltage of the operational amplifier.

### DETAILED DESCRIPTION

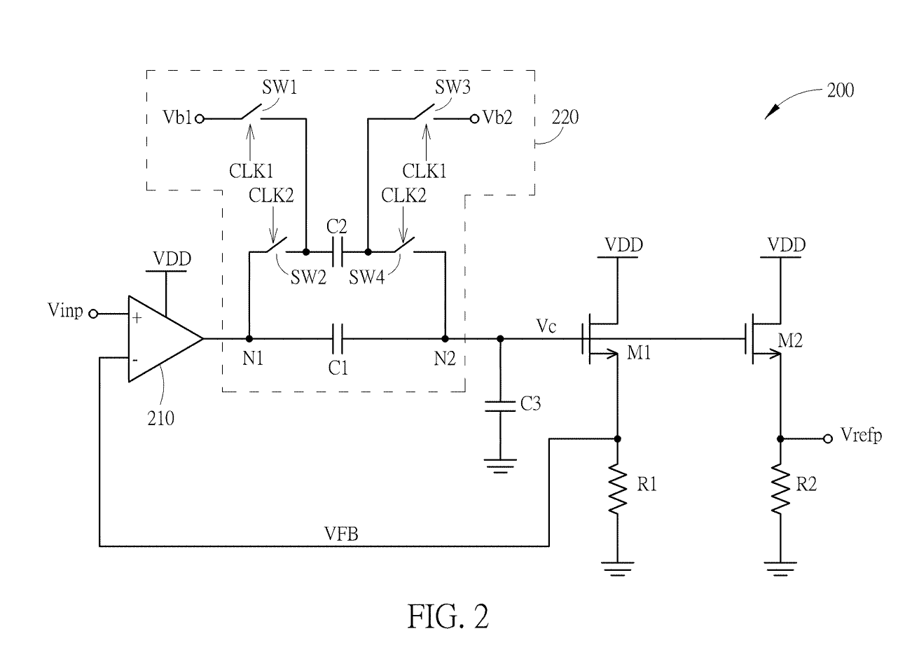

Please refer to FIG. 2, which is a diagram illustrating a reference voltage buffer circuit 200 applied to an analog-to-digital converter according to one embodiment of the present invention. The reference voltage buffer circuit 200 is arranged to receive an input reference voltage Vinp to generate an output reference voltage Vrefp, where voltage levels of the output reference voltage Vrefp and the input reference voltage Vinp are substantially the same. As shown in FIG. 2, the reference voltage buffer circuit 200 comprises an operational amplifier 210, a capacitor switching module 220, two transistors M1 and M2, a capacitor C3, and two resistors R1 and R2. The capacitor switching module 220 comprises two capacitors C1 and C2 connected in parallel, where two terminals N1 and N2 of the capacitor C1 are coupled to an output terminal of the operational amplifier 210 and gate electrodes of the transistors M1 and M2, respectively. In addition, the capacitor switching module 220 comprises four switches SW1-SW4, where the switch SW1 is used to selectively connect a terminal of the capacitor C2 to a bias voltage Vb1, the switch SW2 is used to selectively connect the terminal of the capacitor C2 to the output terminal of the operational amplifier 210 (i.e. the terminal N1), the switch SW3 is used to selectively connect another terminal of the capacitor C2 to a bias voltage Vb2, and the switch SW4 is used to selectively connect the other terminal of the capacitor C2 to the gate electrodes of the transistors M1 and M2 (i.e. the terminal N2).

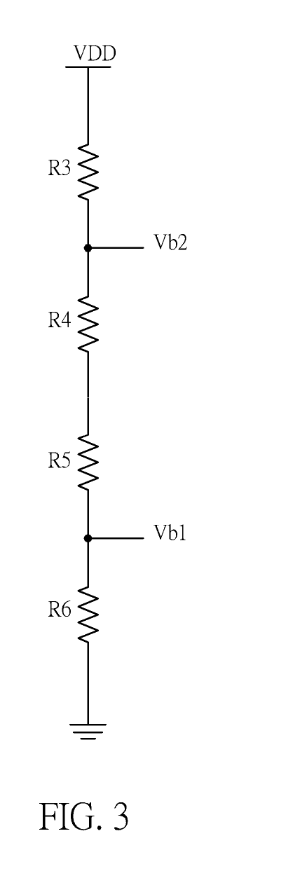

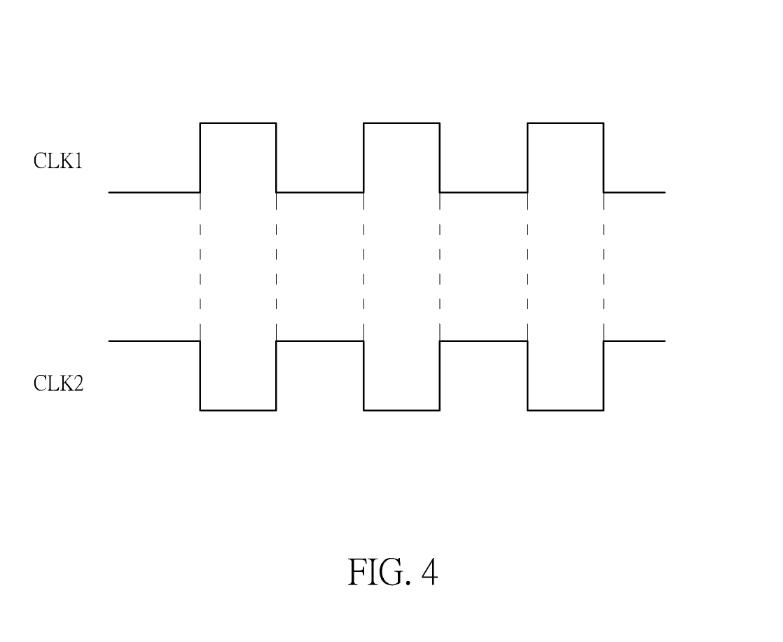

In this embodiment, the operational amplifier 210 has two input terminals, and the two input terminals receive the input reference voltage Vinp and a feedback voltage VFB from a source electrode of the transistor M1, respectively. The bias voltages Vb1 and Vb2 of the capacitor switching module 220 can be generated from a voltage divider (e.g. resistors R3-R6 as shown in FIG. 3), the switches SW1 and SW3 are controlled by a clock signal CLK1 as shown in FIG. 4, the switches SW2 and SW4 are controlled by a clock signal CLK2 as shown in FIG. 4, where phases of the clock signals CLK1 and CLK2 are inverted, and the capacitor switching module 220 generates a stable control signal Vc to the gate electrodes of the transistors M1 and M2 according an output of the operational amplifier 210. In addition, the transistor M1 generates the feedback voltage VFB to the operational amplifier 210 according to the control signal Vc to form a negative feedback loop, and the transistor M2 generates the output reference voltage Vrefp according to the control signal Vc.

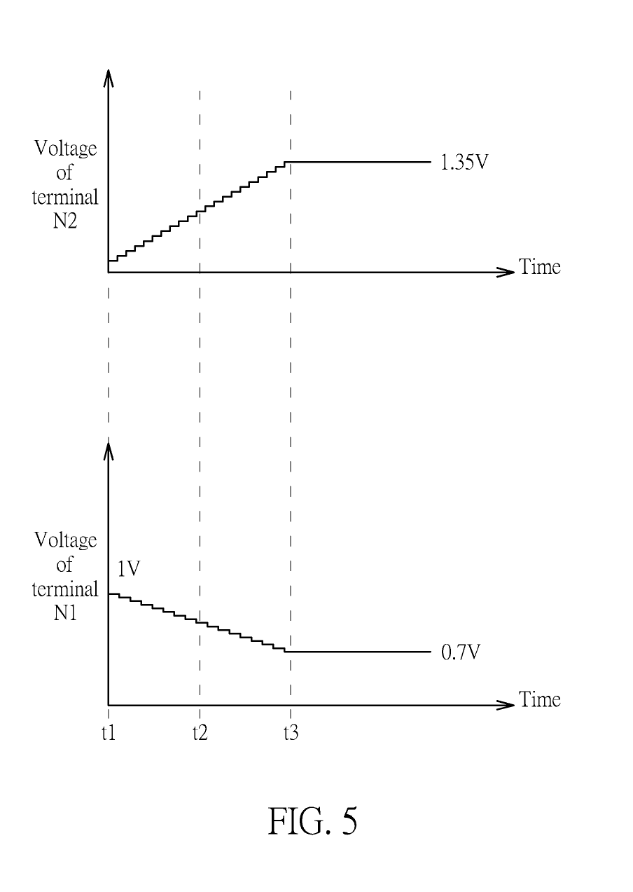

In detail, referring to FIGS. 2-5 together, FIG. 5 is a timing diagram of voltages of the terminals N1 and N2. For illustrative purposes, without a limitation of the present invention, it is assumed that VDD=1V, Vb1=0.25V, Vb2=0.75V, Vinp=0.88V, C1=500 fF, C2=200 fF and C3=4000 fF. In the operations of the reference voltage buffer circuit 200, a time t1 shown in FIG. 5 is an initial status of the circuits, that is the reference voltage buffer circuit 200 starts to be supplied by the supply voltage VDD, at this time the voltage level of the terminal N2 is close to zero (i.e. the control signal Vc is equal to 0V), and the feedback voltage VFB is also close to zero. Then, because of the very low feedback voltage VFB (VFB˜0) and the large input reference voltage (Vinp=0.88V), the output voltage of the operational amplifier 210 is close to the supply voltage VDD due to a large voltage difference of the input signals. In this embodiment, the output voltage of the operational amplifier 210, that is the voltage level of the terminal N1, is about 1V.

After the time t1, by using the clock signals CLK1 and CLK2 to alternately switch on and switch off the switches SW1-SW4, the capacitor C2 can be charged by the bias voltage Vb2 continuously, and the capacitor C2 continuously provide electric charges to the terminal N2 to pull up the gate voltages of the transistors M1 and M2 (i.e. the voltage level of the terminal N2). In detail, when the clock signal CLK1 is at a high level and the clock signal CLK2 is at a low level, the switches SW1 and SW3 are turned on, and the switches SW2 and SW4 are turned off, at this time the two terminals of the capacitor C2 are connected to the bias voltages Vb1 and Vb2, respectively, and the bias voltages Vb1 and Vb2 charge the capacitor C2. Then, when the clock signal CLK1 is at the low level and the clock signal CLK2 is at the high level, the switches SW2 and SW4 are turned on, and the switches SW1 and SW3 are turned off, at this time the capacitor C2 provides electric charges to the terminal N2 to pull up a DC voltage level of the terminal N2. When the voltage level of the terminal N2 increases, the feedback voltage VFB increases accordingly to lower the voltage difference of the input signals of the operational amplifier 210, thereby the output voltage of the operational amplifier 210 decreases (i.e. the voltage level of the terminal N1 decreases). Around a time t2 shown in FIG. 5, the voltage level of the terminal N2 continuously increases, and the voltage level of the terminal N1 continuously decreases. In other words, by using the aforementioned operations, a voltage across the capacitor C1 approaches to a voltage across the capacitor C2 gradually.

At a time t3 shown in FIG. 5, the entire circuits is in a steady state (i.e., the negative feedback loop is in a steady state). In this embodiment, in the steady state, the voltage level of the terminal N1 is about 0.7V, the voltage level of the terminal N1 is about 1.3V, and the feedback voltage VFB is about 0.88V. In light of above, because the voltage level of the terminal N2 is greater than the supply voltage VDD in the steady state, the reference voltage buffer circuit 200 can successfully generate the output reference voltage Vrefp by using only one supply voltage VDD having a lower level. In addition, after the time t3, the switches SW1-SW4 are still controlled by the clock signals CLK1 and CLK2 to be on and off alternately. Because the capacitance of the capacitor C3 is much greater than the capacitance of the capacitor C2, and the voltage across the capacitor C2 (i.e. Vb2−Vb1) is designed to be close to the voltage across the capacitor C1 in the steady state, therefore the reference voltage buffer circuit 200 can keep staying in the steady state.

In addition, the reference voltage buffer circuit 200 applied in the analog-to-digital converter generally requires two reference voltages, the reference voltage Vrefp shown in FIG. 2 can serve as one of the two reference voltages, and a ground voltage can be used as the other one of the two reference voltages.

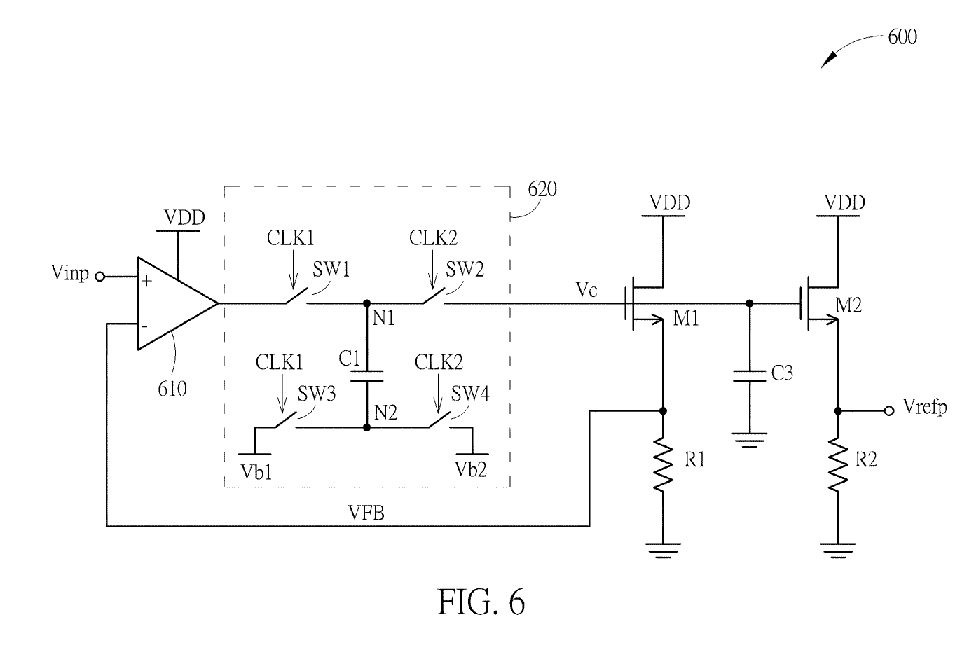

Please refer to FIG. 6, which is a diagram illustrating a reference voltage buffer circuit 600 applied to an analog-to-digital converter according to one embodiment of the present invention. The reference voltage buffer circuit 600 is arranged to receive an input reference voltage Vinp to generate an output reference voltage Vrefp, where voltage levels of the output reference voltage Vrefp and the input reference voltage Vinp are substantially the same. As shown in FIG. 6, the reference voltage buffer circuit 600 comprises an operational amplifier 610, a capacitor switching module 620, two transistors M1 and M2, a capacitor C3, and two resistors R1 and R2. The capacitor switching module 620 comprises a capacitor C1 and four switches SW1-SW4, where the switch SW1 is used to selectively connect a terminal N1 of the capacitor C1 to an output terminal of the operational amplifier 610, the switch SW2 is used to selectively connect the terminal N1 to the gate electrodes of the transistors M1 and M2, the switch SW3 is used to selectively connect a terminal N2 of the capacitor C1 to a bias voltage Vb1, and the switch SW4 is used to selectively connect the terminal N2 of the capacitor C1 to a bias voltage Vb2.

In this embodiment, the operational amplifier 610 has two input terminals, and the two input terminals receive the input reference voltage Vinp and a feedback voltage VFB from a source electrode of the transistor M1. The bias voltages Vb1 and Vb2 of the capacitor switching module 620 can be generated from a voltage divider shown in FIG. 3, the switches SW1 and SW3 are controlled by the clock signal CLK1 shown in FIG. 4, the switches SW2 and SW4 are controlled by the clock signal CLK2 shown in FIG. 4, where phases of the clock signals CLK1 and CLK2 are inverted, and the capacitor switching module 620 generates a stable control signal Vc to the gate electrodes of the transistors M1 and M2 according an output of the operational amplifier 610. In addition, the transistor M1 generates the feedback voltage VFB to the operational amplifier 610 according to the control signal Vc to form a negative feedback loop, and the transistor M2 generates the output reference voltage Vrefp according to the control signal Vc.

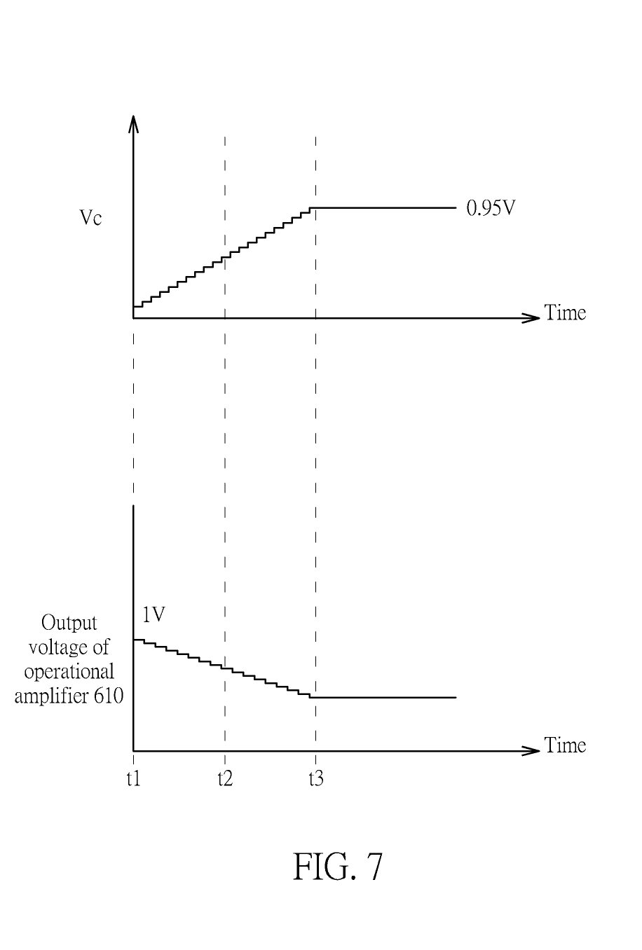

In detail, referring to FIGS. 6 and 7 together, FIG. 7 is a timing diagram of the control voltage Vc and the output voltage of the operational amplifier 610. For illustrative purposes, without a limitation of the present invention, it is assumed that VDD=1V, Vb1=0V, Vb2=0.7V, Vinp=0.8V, C1=40 fF, C3=1000 fF and C3=4000 fF. In the operations of the reference voltage buffer circuit 600, a time t1 shown in FIG. 7 is an initial status of the circuits, that is the reference voltage buffer circuit 600 starts to be supplied by the supply voltage VDD, at this time the control signal Vc is equal to 0V, so the feedback voltage VFB is also close to zero. Then, because of the very low feedback voltage VFB (VFB˜0) and the large input reference voltage (Vinp=0.8V), the output voltage of the operational amplifier 610 is close to the supply voltage VDD due to a large voltage difference of the input signals. In this embodiment, the output voltage of the operational amplifier 610 is about 1V.

After the time t1, by using the clock signals CLK1 and CLK2 to alternately switch on and switch off the switches SW1-SW4, the electric charges provided by the bias voltages Vb1 and Vb2 are stored into the capacitor C1 first, then these electric charges are shared to the capacitor C3, to continuously pull up the control voltage Vc. In detail, when the clock signal CLK1 is at a high level and the clock signal CLK2 is at a low level, the switches SW1 and SW3 are turned on, and the switches SW2 and SW4 are turned off, at this time the two terminals N1 and N2 of the capacitor C1 are connected to the output terminal of the operational amplifier 610 and the bias voltage Vb1, respectively. Then, when the clock signal CLK1 is at the low level and the clock signal CLK2 is at the high level, the switches SW2 and SW4 are turned on, and the switches SW1 and SW3 are turned off, at this time the two terminals N1 and N2 of the capacitor C1 are connected to the gate electrodes of the transistors M1 and M2 and the bias voltage Vb2, respectively, and because the bias voltage Vb2 is greater than the bias voltage Vb1, the voltage level of the terminal N1 increases and the electric charges are provided to the terminal of the capacitor C3, that is the control voltage Vc increases accordingly. In addition, because the control voltage Vc increases, the feedback voltage VFB increases accordingly to lower the voltage difference of the input signals of the operational amplifier 610, thereby the output voltage of the operational amplifier 610 decreases. Around a time t2 shown in FIG. 7, the control voltage Vc continuously increases, and the output voltage of the operational amplifier 610 continuously decreases.

At a time t3 shown in FIG. 7, the entire circuits is in a steady state (i.e., the negative feedback loop is in a steady state). In this embodiment, in the steady state, the control voltage Vc is about 0.95V, and the feedback voltage VFB is about 0.8V. In addition, after the time t3, the switches SW1-SW4 are still controlled by the clock signals CLK1 and CLK2 to be on and off alternately. Because the capacitance of the capacitor C3 is much greater than the capacitance of the capacitor C1, and the voltages across the capacitor C3 under different switching states are designed to be close (i.e. in the steady state, a different between the output voltage of the operational amplifier 610 and the bias voltage Vb1 is similar to (Vc−Vb2)), therefore the reference voltage buffer circuit 600 can keep staying in the steady state.

In addition, the reference voltage buffer circuit 600 applied in the analog-to-digital converter generally requires two reference voltages, the reference voltage Vrefp shown in FIG. 6 can serve as one of the two reference voltages, and a ground voltage can be used as the other one of the two reference voltages.

Briefly summarized, in the reference voltage buffer circuit of the present invention, the operational amplifier generates the stable control voltage Vc to the gate electrodes of transistors M1 and M2 via the capacitor switching module 220/620, but the output terminal of the operational amplifier does not directly connect to the transistors M1 and M2 at any time. By using the operations of the capacitor switching module 220/620, the reference voltage buffer circuit can successfully generate the output reference voltage by using only one supply voltage having a lower level.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A reference voltage buffer circuit, comprising:
an operational amplifier comprises two input terminals and an output terminal, where the two input terminals are arranged to receive an input reference voltage and a feedback voltage;
a capacitor switching module, coupled to the output terminal of the operational amplifier;
a first transistor, wherein a gate electrode of the first transistor is coupled to the capacitor switching module, and a source electrode of the first transistor is arranged to provide the feedback voltage; and
a second transistor, wherein a gate electrode of the second transistor is coupled to the capacitor switching module, and a source electrode of the second transistor is arranged to provide an output reference voltage
wherein the operational amplifier generates a stable control voltage to the gate electrodes of the first transistor and the second transistors via the capacitor switching module while the output terminal of the operational amplifier is not directly connect to the gate electrodes of the first transistor and the second transistors.

2. The reference voltage buffer circuit of claim 1, wherein the capacitor switching module comprises:
a first capacitor, coupled between the output terminal of the operational amplifier and the gate electrode of the first transistor;
a second capacitor, coupled between the output terminal of the operational amplifier and the gate electrode of the first transistor, wherein the first capacitor and the second capacitor are connected in parallel; and
a plurality of switches, for selectively connecting a first terminal of the second capacitor to a first bias voltage or the output terminal of the operational amplifier, and selectively connecting a second terminal of the second capacitor to a second bias voltage or the gate electrode of the first transistor.

3. The reference voltage buffer circuit of claim 2, wherein the plurality of switches comprises:
a first switch, for selectively connecting the first terminal of the second capacitor to the first bias voltage;
a second switch, for selectively connecting the first terminal of the second capacitor to the output terminal of the operational amplifier;
a third switch, for selectively connecting the second terminal of the second capacitor to the second bias voltage; and
a fourth switch, for selectively connecting the second terminal of the second capacitor to the gate electrode of the first transistor.

4. The reference voltage buffer circuit of claim 3, wherein the first switch and the third switch are controlled by a first clock signal, the second switch and the fourth switch are controlled by a second clock signal, and phases of the first clock signal and the second clock signal are inverted.

5. The reference voltage buffer circuit of claim 3, wherein the second bias voltage is greater than the first bias voltage.

6. The reference voltage buffer circuit of claim 1, wherein the operational amplifier, the capacitor switching module, the first transistor and the second transistor are supplied by a same supply voltage, and the stable control voltage is greater than the supply voltage.

7. The reference voltage buffer circuit of claim 1, wherein the capacitor switching module comprises:
a plurality of switches; and
a capacitor comprising a first terminal and a second terminal, wherein the first terminal is selectively coupled to the output terminal of the operational amplifier or the gate electrode of the first transistor via the plurality of switches, and the second terminal is selectively coupled to a first bias voltage or a second bias voltage via the plurality of switches.

8. The reference voltage buffer circuit of claim 7, wherein the plurality of switches comprises:
a first switch, for selectively connecting the first terminal of the capacitor to the output terminal of the operational amplifier;
a second switch, for selectively connecting first terminal of the capacitor to the gate electrode of the first transistor;
a third switch, for selectively connecting the second terminal of the capacitor to the first bias voltage; and
a fourth switch, for selectively connecting the second terminal of the capacitor to the second bias voltage.

9. The reference voltage buffer circuit of claim 8, wherein the first switch and the third switch are controlled by a first clock signal, the second switch and the fourth switch are controlled by a second clock signal, and phases of the first clock signal and the second clock signal are inverted.

10. The reference voltage buffer circuit of claim 8, wherein the second bias voltage is greater than the first bias voltage.
